(19) United States
(12) Patent Application Publication
(10) Pub. No.: US 2009/0050953 A1
(43) Pub. Date: Feb. 26, 2009

(54) NON-VOLATILE MEMORY DEVICE AND METHOD FOR MANUFACTURING THE SAME

(75) Inventors: Szu-Yu Wang, Kaohsiung City (TW); Hang-Ting Lue, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MACRONIX INTERNATIONAL CO., LTD., Hsinchu (TW)

(21) Appl. No.: 11/842,990

(22) Filed: Aug. 22, 2007

(51) Int. Cl. H01L 29/792; H01L 21/336

(52) U.S. Cl. 257/324; 438/287; 257/E29.309; 257/E21.423

(57) ABSTRACT

A non-volatile memory device including a substrate, an insulating layer, a charge storage layer, a multi-layer tunneling dielectric structure and a gate is provided. The substrate has a channel region. The insulating layer is disposed on the channel region. The charge storage layer is disposed on the insulating layer. The multi-layer tunneling dielectric structure is disposed on the charge storage layer. The gate is disposed on the multi-layer tunneling dielectric structure and the charge carriers are injected from the gate.

### BACKGROUND OF THE INVENTION

1. Field of the Invention

The invention relates in general to a non-volatile memory device and a method for manufacturing the same, and more particularly to a non-volatile memory device having multi-layer tunneling dielectric structure and injecting charge carriers from the gate and a method for manufacturing the same.

2. Description of the Related Art

Non-volatile memory device is a semiconductor memory device which stores the data even after the power is off. Examples of conventional non-volatile memory device include mask read-only memory (mask ROM), erasable programmable read-only memory, electrically erasable programmable memory and flash memory.

Floating gate devices share mostly in the current flash memory market. In this kind of flash memories, an array is formed by a number of memory units. Each memory unit mainly comprises a metal oxide semiconductor (MOS) transistor. The MOS transistor comprises a gate, a source, a drain, and a channel disposed between the source and the drain. The gate is a dual-gate structure comprising a floating gate. The floating gate is contained between two dielectric layers and is used as a charge storage layer, which changes the threshold voltage of the channel by injecting charge carriers to the floating gate. When a reading bias voltage is applied to the gate, the readings of the current obtained under different threshold voltages are different so as to denote the difference in bit states.

In recent years, the floating gate devices have suffered some scaling issues such as gate coupling issue and therefore, some other potential applications such as charge-trapping-mamories arise for further scaling of flash memories. SONOS-type devices are the devices that have attracted big attention to replace floating gate devices as the scaling solutions. For the memory device with SONOS structure, the ultra-thin tunneling dielectric layer easily enhances the tunneling efficiency of both electron and hole so that the programming and erasing operations are made faster. However, the serious charge loss under retention states is the problem. On the other hand, although the retention problem is overcome by applying thicker tunneling dielectric in nitride read-only-memory devices, the required powerful erasing operation such as band-to-band tunneling hot hole (BTBTHH) tunneling will easily damage the tunneling dielectric layer and affect the reliability and durability of the memory device.

### SUMMARY OF THE INVENTION

The invention is directed to a non-volatile memory device and a method for manufacturing the same. A multi-layer tunneling dielectric structure is disposed between the gate and the charge storage layer, and charge carriers are injected from the gate for changing the state of stored bits. The multi-layer tunneling structure effectively prevents the leakage of stored charge carriers. Meanwhile, when a bias voltage is applied to the gate, charge carriers can tunnel at a faster rate.

According to a first aspect of the present invention, a non-volatile memory device including a substrate, an insulating layer, a charge storage layer, a multi-layer tunneling dielectric structure and a gate is provided. The substrate has a channel region. The insulating layer is disposed on the channel region. The charge storage layer is disposed on the insulating layer. The multi-layer tunneling dielectric structure is disposed on the charge storage layer. The gate is disposed on the multi-layer tunneling dielectric structure.

According to a second aspect of the present invention, a method for manufacturing a non-volatile memory device is provided. The method includes the following steps. First, an insulating layer is formed on a substrate, wherein the substrate has a channel region, and the insulating layer is disposed on the channel region. Next, a charge storage layer is formed on the insulating layer. Then, a multi-layer tunneling dielectric structure is formed on the charge storage layer. Afterwards, a gate is formed on the multi-layer tunneling dielectric structure.

The invention will become apparent from the following detailed description of the preferred but non-limiting embodiments. The following description is made with reference to the accompanying drawings.

### BRIEF DESCRIPTION OF THE DRAWINGS

FIG. 1 is a perspective of a non-volatile memory device according to a preferred embodiment of the invention;

FIG. 2A is an energy band diagram of the non-volatile memory device of the invention before a positive bias voltage is applied to the gate;

FIG. 2B is an energy band diagram of the non-volatile memory device of the invention after a positive bias voltage is applied to the gate;

FIG. 3A is an energy band diagram of another non-volatile memory device of the invention;

FIG. 3B is a distribution diagram of nitrogen concentration corresponding to the memory structure of FIG. 3A;

FIGS. 4A-4H are manufacturing diagrams of the non-volatile memory device according to a preferred embodiment of the invention; and

FIG. 5 is a manufacturing flowchart of the non-volatile memory device according to a preferred embodiment of the invention.

### DETAILED DESCRIPTION OF THE INVENTION

Referring to FIG. 1, a perspective of a non-volatile memory device according to a preferred embodiment of the invention is shown. The non-volatile memory device 10 comprises a substrate 100, an insulating layer 110a, a charge storage layer 120a, a multi-layer tunneling dielectric structure 130a and a gate 140b. The substrate 100 has a channel region 106, a source region 102 and a drain region 104, wherein the source region 102 and the drain region 104 are interspaced by the channel region 106, and the insulating layer 110a is disposed on the channel region 106. The charge storage layer 120a is disposed on the insulating layer 110a. The multi-layer tunneling dielectric structure 130a is disposed on the charge storage layer 120a. The gate 140b is disposed on the multi-layer tunneling dielectric structure 130.

The non-volatile memory device 100 differs with a memory device with SONOS structure in that the non-volatile memory device 100 replaces the tunneling dielectric layer disposed between the charge storage layer and the charge injection source by a multi-layer tunneling dielectric structure 130 comprising a first dielectric layer 136a, a second dielectric layer 134a and a third dielectric layer 132a. The third dielectric layer 132a is disposed on the charge storage layer 120a. The second dielectric layer 134a is disposed on the third dielectric layer 132a. The first dielectric layer 136a is disposed on the second dielectric layer 134a. Of the three-layered structure, at least the second dielectric layer 134a contains nitrogen (N). The third dielectric layer 132a, the second dielectric layer 134a and the first dielectric layer 136a are respectively made from oxide, nitride and oxide. Examples of the oxide includes silicon oxide and silicon oxynitride. Examples of the nitride includes silicon nitride and silicon oxynitride. Besides, the second dielectric layer 134a can be made from some high-k materials, such as hafnium oxide (HfO₂) or aluminum oxide (Al₂O₃). That is, the non-volatile memory device 10 has an SONONOS structure, or a so-called bandgap-engineered SONOS (BE-SONOS) structure.

The thickness of different dielectric layer may have different ragnes. For example, the thickness of the first dielectric layer 136a may be less than 20 angstroms (Å), range between 5 Å-20 Å, or be less than 15 Å. The thickness of the second dielectric layer 134a may be less than 20 Å or range between 10 Å-20 Å. The thickness of the third dielectric layer 132a may be less than 20 Å or range between 15 Å-20 Å.

Furthermore, the charge storage layer 120a can be made from silicon nitride (SiN), silicon oxynitride (SiON), hafnium oxide (HfO₂) or aluminum oxide (Al₂O₃), or can be made from the same material with the second dielectric layer 134a. The insulating layer 110a can be made from silicon oxide, or silicon oxynitride (SiON), or made from the same material as the third dielectric layer 132a and the first dielectric layer 136a. The gate 140b can be made from metal, polycrystalline silicon, metal silicide or a combination thereof. That is, a film stack is formed by incorporating a polycrystalline silicon layer with a metal layer or a metal silicide layer. For example, the gate is made from polycrystalline silicon incorporated with tungsten silicide.

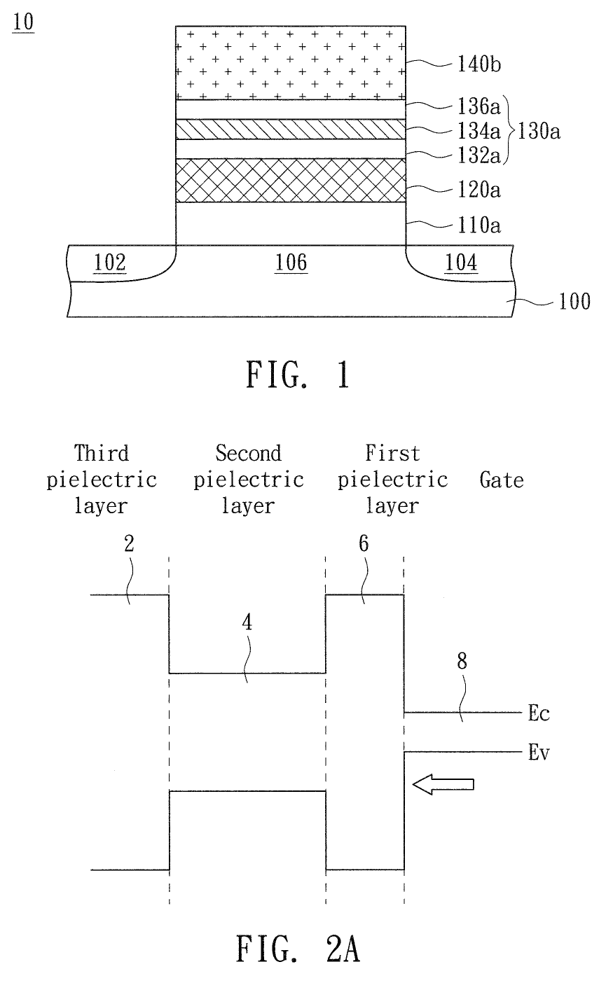

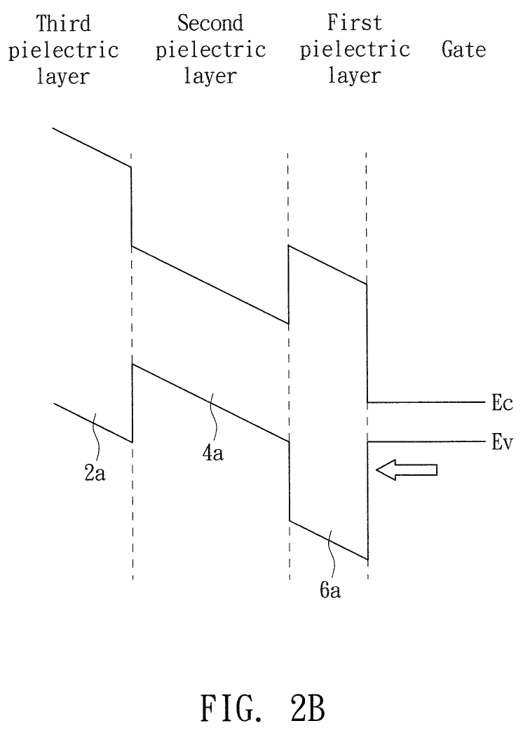

Referring to FIGS. 2A and 2B. FIG. 2A is an energy band diagram of the non-volatile memory device of the invention before a positive bias voltage is applied to the gate. FIG. 2B is an energy band diagram of the non-volatile memory device of the invention after a positive bias voltage is applied to the gate. As indicated in FIG. 2A, the energy bands 2, 4, 6, 8 respectively are the energy band of the third dielectric layer 132a, the energy band of the second dielectric layer 134a, the energy band of the first dielectric layer 136a and the energy band of the gate 140b. Presuming that the third dielectric layer 132a, the second dielectric layer 134a, and the first dielectric layer 136a are respectively made from silicon oxide, silicon nitride, and silicon oxide. As the second dielectric layer 134a is a nitride, the conductive energy barrier and the valence energy barrier of the second dielectric layer 134a are smaller than that of the third dielectric layer 132a and the first dielectric layer 136a respectively. For a hole to be injected from the gate 140b under the state of FIG. 2A, the hole must tunnel through the energy bands 2, 4, and 6 before the hole can reach the charge storage layer 120a. On the contrary, for a hole to escape from the gate end, the hole of the charge storage layer 120a must tunnel through the energy bands 2, 4, and 6, too. Therefore, when no bias voltage or only a small bias voltage is applied to the gate 140b, the charge storage layer 120a is well shielded, and no charge will be injected or escape.

FIG. 2B illustrates the situation when a positive bias voltage having a specific level of voltage is applied to the gate. As a positive bias voltage is applied to the gate, the energy bands 2, 4, and 6 of FIG. 2A generate a relative shift as that in FIG. 2B and become the energy bands 2a, 4a, and 6a. Meanwhile, when holes are injected from the gate electrode, the effective tunneling barrier is reduced merely as the energy band 6a. The first dielectric layer 136a is so thin, hence producing the effect like direct tunneling and speeding the operation. As the probability that the accelerated carriers should collide with the molecules of the first dielectric layer 136a is very small, and the first dielectric layer 136a is hardly damaged. Consequently, the reliability and durability of the overall elements are improved.

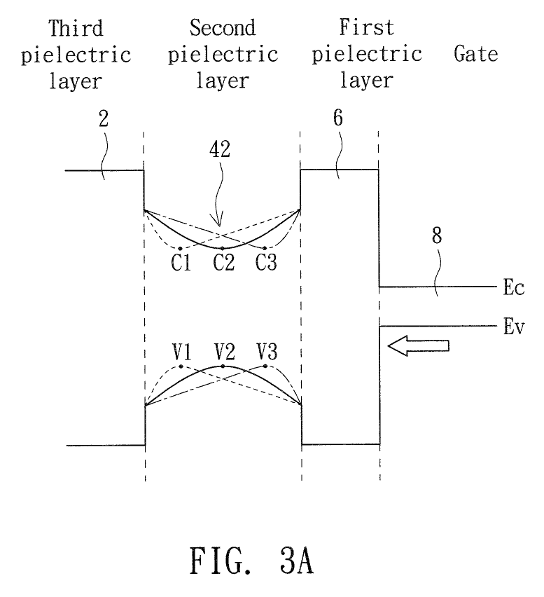

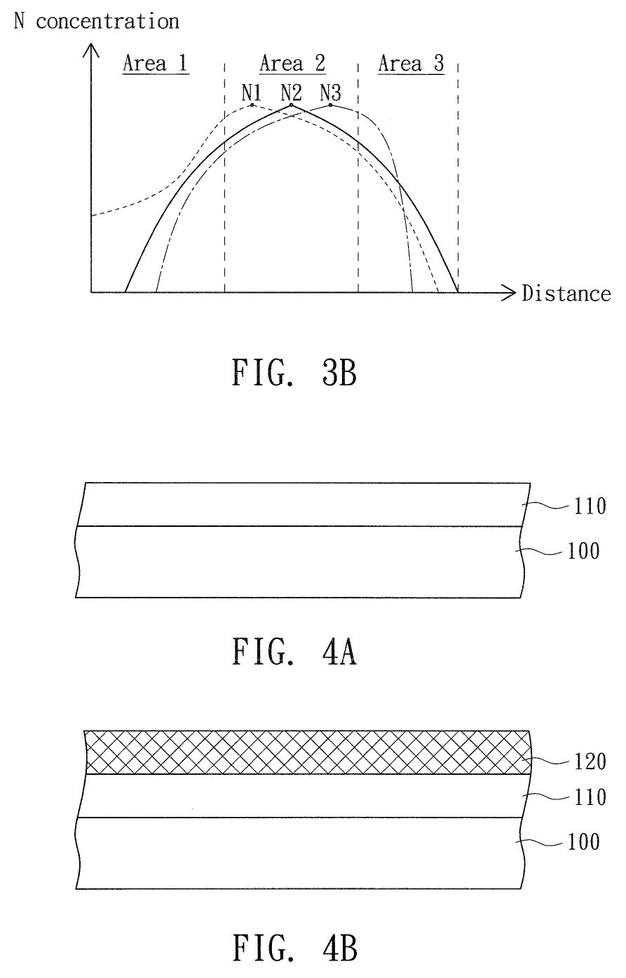

The third dielectric layer 132a, the second dielectric layer 134a and the first dielectric layer 136a consist essentially of silicon (Si), nitride (N) and oxygen (O). The proportions of elements are different for each layer, and the region containing the largest nitrogen concentration is located within the second dielectric layer 134a. Also referring to FIG. 3A and FIG. 3B. FIG. 3A is an energy band diagram of another non-volatile memory device of the invention. FIG. 3B is a distribution diagram of nitrogen concentration corresponding to the memory structure of FIG. 3A. As indicated in FIG. 3A, the tunneling layer may have three types of energy band distributions just like the energy band set 42. The three types of energy band distributions denote that a certain region within the tunneling layer respectively has the smallest conductive energy barrier height among C1, C2 and C3 and the largest valence energy barrier height among V1, V2 and V3. That is, as long as the conductive energy level (Ec) of at least one region within the second dielectric layer 134a is lower than that of the third dielectric layer 132a and the first dielectric layer 136a, and the valence energy level (Ev) of the region is higher than that of the third dielectric layer 132a and the first dielectric layer 136a will do.

As indicated in FIG. 3B, Area 1, Area 2 and Area 3 respectively are a region within the third dielectric layer 132a, the second dielectric layer 134a and the first dielectric layer 136a. The abovementioned (C1, V1), (C2, V2) and (C3, V3) respectively correspond to the nitrogen concentration N1, N2 and N3 of FIG. 3B. That is, in the second dielectric layer 134a, the location with the smallest energy barrier is the location with the largest nitrogen concentration. That is, as long as the nitrogen concentration of at least one region of the second dielectric layer 134a is larger than the nitrogen concentration of the third dielectric layer 132a and the first dielectric layer 136a, the memory device is able to perform charge direct tunneling effect when receiving a bias voltage having certain voltage level. And the memory device is able to maintain the stability of the stored charge carriers when none or little bias voltage is applied to the gate electrode 140b.

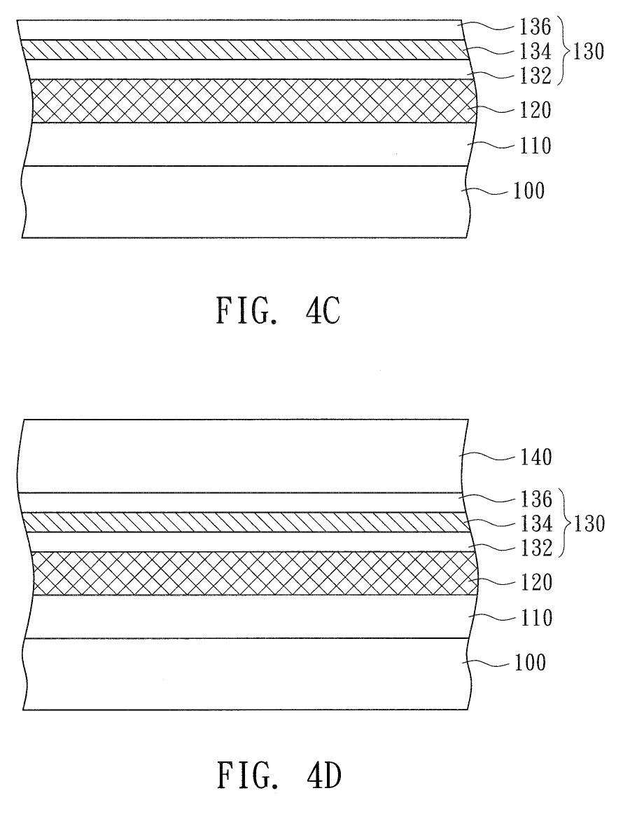

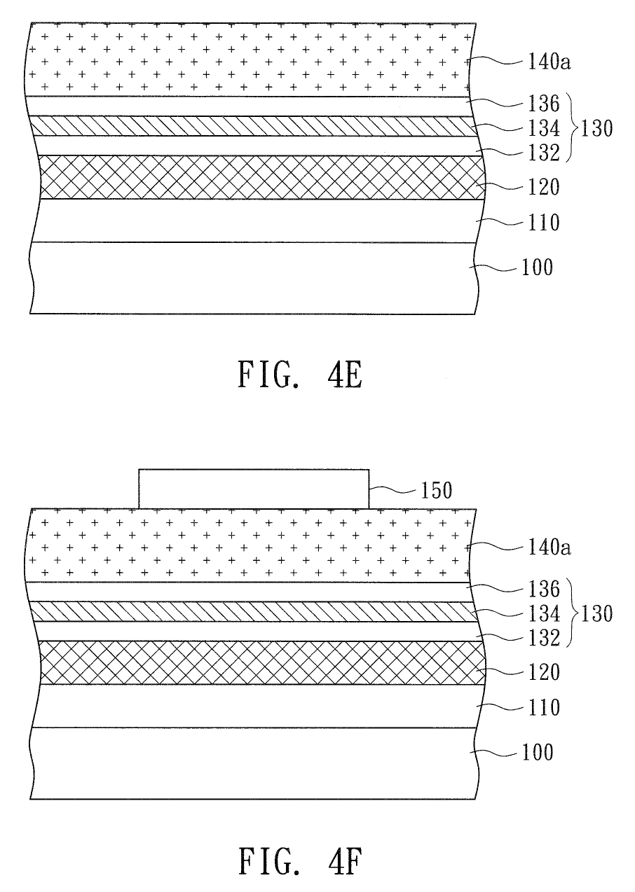

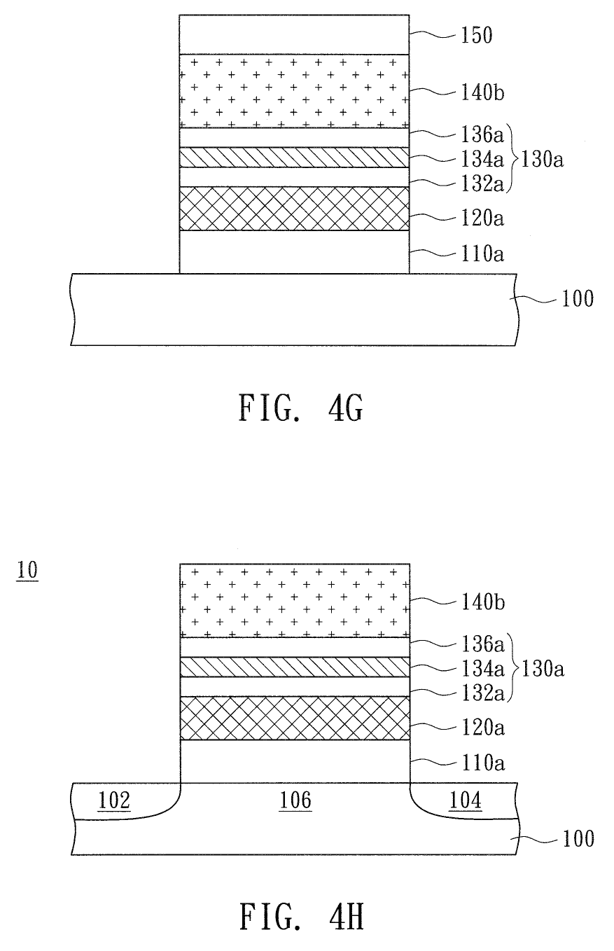

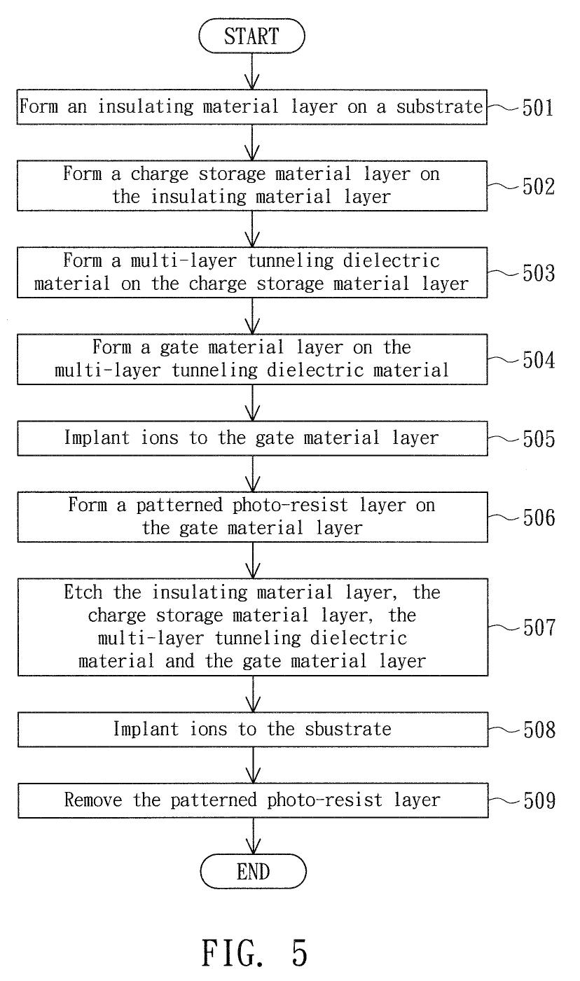

Referring to FIGS. 4A-4G, manufacturing diagrams of the non-volatile memory device according to a preferred embodiment of the invention are shown. Also referring to FIG. 5, a manufacturing flowchart of the non-volatile memory device according to a preferred embodiment of the invention is shown. Referring to FIG. 4A, as indicated in step 501, an insulating material layer 110 is formed on the substrate 100. The step 501 can deposit a silicide material such as SiO or SiON on the substrate 100 to form the insulating material according to furnace oxidation, rapid thermal oxidation (RTO), chemical vapor deposition (CVD), in-situ steam generation (ISSG), plasma oxidation, plasma nitridation, or the combination and application of above mentioned processes. After the material is formed, the annealing process can be performed under the ambient of N, O, and argon (Ar). If nitridation is required, the nitridizing process can be performed before, during or after the oxidizing process. Besides, SiN or SiON can be deposited first, and partially or completely oxidized as an SiON layer next.

Next, referring to FIG. 4B. As indicated in step 502, a charge storage material layer 120 is formed on the insulating material layer 110. The step 502 can deposit a silicide material containing nitrogen such as SiN or SiON on the insulating material layer 110, wherein the lowest Ec of the silicide material must be smaller than that of the insulating material layer 110, and the largest Ev must be larger than that of the insulating material layer 110. Likewise, the step 502 can form the charge storage material layer 120 according to SiN or SiON film deposition by CVD processes. If further nitridation process is required, it can be performed by the thermal treatments in which the ambient consists at least one of NO, N2O, NH3, and ND3. In addition, plasma nitridation is also applicable for this purpose. In spite of the CVD processes, the step 502 can convert part of the insulating material layer 110 into SiON or SiN directly by plasma nitridation. Or, by plasma nitridation first, and then performing the process of CVD SiN or SiON deposition. The further annealing process is optional with the ambient of N₂, O₂, Ar, NO, N₂O, NH₃, or ND₃. The nitridizing process can be performed before, during or after any of the above manufacturing under the ambient of N₂O, NO, NH₃ or ND₃. Or, hafnium oxide (HfO₂) or aluminum oxide (Al₂O₃) is deposited as the charge storage material layer 120.

Then, referring to FIG. 4C. As indicated in step 503, a multi-layer tunneling dielectric material 130 is formed on the charge storage material layer 120. The step 503 further forms the third dielectric material layer 132 on the charge storage material layer 120. Like the step 501, the step can deposit a silicide material on the charge storage material layer 120 first and then oxidize the silicide material layer next. Afterwards, a second dielectric material layer 134 is formed on the third dielectric layer 132, wherein the second dielectric material layer 134 contains nitrogen. Like the step 502, the step 503 can deposit a silicide material on the third dielectric layer 132 first and nitridize the silicide material next. Then, a first dielectric material layer 136 is formed on the second dielectric material layer 134. Like the step 501, the step can deposit a silicide material on the second dielectric material layer 134 first and oxidize the silicide material next.

The multi-layer tunneling dielectric material 130 can also be formed by successive oxidation, nitridation, and CVD deposition processes. That is, anyone of the first and third dielectric layers can be formed by oxidation processes by furnace, RTO, ISSG, or plasma oxidation with the ambient of H₂, O₂, H₂O_{(g)}, NO, or N₂O. The CVD deposition of silicon oxide or silicon oxynitride (SiON) is also applicable. The post annealing process is optional with the ambient of N₂, O₂, Ar, NO, N₂O, NH₃, or ND₃. The nitridizing processes can be performed before, during or after any of the above manufacturing. Both thermal nitridation under the ambient of N₂O, NO, NH₃ or ND₃, or the plasma nitridation process are applicable. The second dielectric layer can be SiN or SiON material and directly deposited by CVD processes, or, by nitridizing partial of the third dielectric layer into N-containing material. The post annealing process is optional with the ambient of N₂, O₂, Ar, NO, N₂O, NH₃, or ND₃. The post nitridation by plasma nitridation process is also optional.

The high-k materials such as hafnium oxide (HfO₂) or aluminum oxide (Al₂O₃), is also applicable to be served as the second dielectric layer 134.

Next, referring to FIG. 4D. As indicated in step 504, a gate material layer 140 is formed on the multi-layer tunneling dielectric material 130. In the present embodiment of the invention, the gate material layer 140 is made from polycrystalline silicon. The metal silicide, such as tungsten silicide, is also applicable to be deposited on the poly silicon gate.

Then, referring to FIG. 4E. As indicated in step 505, the invention preferably applies ion implantation to the gate material layer 140 to form a gate material layer 140a. The step 505 can implant N-type dopants or P-type dopants to the gate material layer 140.

Next, referring to FIG. 4F. As indicated in step 506, a patterned photo-resist layer 150 is formed on the gate material layer 140a after depositing, exposing and developing a photo-resist material (not illustrated).

Then, referring to FIG. 4G. As indicated in step 507, the insulating material layer 110, the charge storage material layer 120, the multi-layer tunneling dielectric material 130 and the gate material layer 140a are etched to form a memory structure according to the patterned photo-resist layer 150.

Next, referring to FIG. 4H. As indicated in step 508, ions are implanted to the substrate 100 to form the source region 102, the drain region 104 so as to define the channel region 106. The channel region 106 is interspaced by the source region 102 and the drain region 104. The insulating layer 110a is disposed on the channel region 106. Then, as indicated in step 509, the patterned photo-resist layer 150 is removed. The non-volatile memory device 10 is completed here. It is noted that the step 509 may be performed before the step 508. Thus, the dopants injected to the gate material layer 140 are the same as that injected to the source region 102 and the drain region 104.

In practical application, the technology of invention is not limited to the above embodiments, and the multi-layer tunneling dielectric structure 130 does not have to include the third dielectric layer 132a. That is, the step 503 does not form the third dielectric material layer 132, but directly form the second dielectric material layer 134 on the charge storage material layer 120. It is noted that the second dielectric material layer 134 and the charge storage material layer 120 can be made from the same material or different materials. For example, both the second dielectric material layer 134 and the charge storage material layer 120 can be made from SiN or SiNO. Even the same material is adopted in different material layers, each material layer can have different distribution of nitrogen concentration such that different energy bands can be formed in different material layers.

According to the non-volatile memory device and the method for manufacturing the same disclosed in the above embodiment of the invention, the multi-layer tunneling dielectric structure replaces the conventional tunneling dielectric layer and is disposed at the gate side, and charge carriers are injected from the gate. Such structure prevents the bias voltage applied to the source region, the drain region or even to the substrate from affecting the charge carriers injection and the storage of charge carriers, meanwhile preventing other manufacturing processes of the substrate, for example, the formation of shallow trench isolation (STI), from affecting a critical tunneling dielectric layer. Compared with the conventional SONOS structure, the structure of the invention has better charge carriers storing ability. Compared with the nitride trapping layer memories structure, the structure of the invention causes very little damage to the tunneling dielectric layer, hence having better durability and reliability.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A non-volatile memory device, comprising:
a substrate comprising a channel region;
an insulating layer disposed on the channel region;
a charge storage layer disposed on the insulating layer;
a multi-layer tunneling dielectric structure disposed on the charge storage layer; and
a gate disposed on the multi-layer tunneling dielectric structure.

2. The non-volatile memory device according to claim 1, wherein the multi-layer tunneling dielectric structure comprises a third dielectric layer, a second dielectric layer and a first dielectric layer, the third dielectric layer is disposed on the charge storage layer, the second dielectric layer is disposed on the third dielectric layer, the first dielectric layer is disposed on the second dielectric layer, and at least the second dielectric layer contains nitrogen (N).

3. The non-volatile memory device according to claim 2, wherein the third dielectric layer, the second dielectric layer and the first dielectric layer consist essentially of silicon (Si), nitrogen (N) and oxygen (O).

4. The non-volatile memory device according to claim 3, wherein the conductive energy band level (Ec) of at least one region of the second dielectric layer is higher than that of the third dielectric layer and the first dielectric layer, and the valence energy band level (Ev) of the at least one region is lower than that of the third dielectric layer and the first dielectric layer.

5. The non-volatile memory device according to claim 3, wherein the nitrogen concentration of at least one region of the second dielectric layer is higher than that of the third dielectric layer and the first dielectric layer.

6. The non-volatile memory device according to claim 2, wherein the third dielectric layer, the second dielectric layer and the first dielectric layer respectively are made from oxide, nitride and oxide.

7. The non-volatile memory device according to claim 2, wherein the third dielectric layer, the second dielectric layer and the first dielectric layer are respectively made from silicon oxide, silicon nitride and silicon oxide.

8. The non-volatile memory device according to claim 2, wherein the third dielectric layer, the second dielectric layer and the first dielectric layer are respectively made form silicon oxide, aluminum oxide and silicon oxide.

9. The non-volatile memory device according to claim 2, wherein thickness of the first dielectric layer is less than 20 angstroms (Å).

10. The non-volatile memory device according to claim 2, wherein thickness of the first dielectric layer ranges between 5 Å-20 Å.

11. The non-volatile memory device according to claim 2, wherein thickness of the first dielectric layer is less than 15 Å.

12. The non-volatile memory device according to claim 2, wherein thickness of the second dielectric layer is less than 20 Å.

13. The non-volatile memory device according to claim 2, wherein thickness of the second dielectric layer ranges between 10 Å-20 Å.

14. The non-volatile memory device according to claim 2, wherein thickness of the third dielectric layer is less than 20 Å.

15. The non-volatile memory device according to claim 2, wherein thickness of the third dielectric layer ranges between 15 Å-20 Å.

16. The non-volatile memory device according to claim 1, wherein the charge storage layer is made from silicon nitride, silicon oxynitride, hafnium oxide or aluminum oxide.

17. The non-volatile memory device according to claim 1, wherein the insulating layer on channel region is made from silicon nitride or silicon oxynitride.

18. The non-volatile memory device according to claim 1, wherein the insulating layer on channel region is made from hafnium oxide or aluminum oxide.

19. The non-volatile memory device according to claim 1, wherein the substrate further comprises a source region and a drain region, the source region and the drain region are interspaced by the channel region.

20. The non-volatile memory device according to claim 1, wherein the insulating layer is made from silicon oxide or silicon oxynitride.

21. The non-volatile memory device according to claim 1, wherein the gate is made from metal, polycrystalline silicon, metal silicide or a combination thereof.

22. The non-volatile memory device according to claim 1, wherein the multi-layer tunneling dielectric structure comprises a second dielectric layer and a first dielectric layer, the second dielectric layer is disposed on the charge storage layer, the first dielectric layer is disposed on the second dielectric layer, and at least the second dielectric layer contains nitrogen.

23. A manufacturing method of a non-volatile memory device, the method comprising:
(a) forming an insulating material layer on a substrate;
(b) forming a charge storage material layer on the insulating material layer;
(c) forming a multi-layer tunneling dielectric material on the charge storage material layer;
(d) forming a gate material layer on the multi-layer tunneling dielectric material;
(e) forming a patterned photo-resist layer on the gate material layer; and
(f) etching the insulating material layer, the charge storage material layer, the multi-layer tunneling dielectric material and the gate material layer according to the patterned photo-resist layer to form a memory structure.

24. The manufacturing method according to claim 23, wherein the step (c) further comprises:
(c1) forming a third dielectric layer on the charge storage material layer;
(c2) forming a second dielectric material layer on the third dielectric layer, wherein the second dielectric material layer contains nitrogen; and
(c3) forming a first dieletric material layer on the second dielectric material layer.

25. The manufacturing method according to claim 24, wherein the step (c1) further comprises:
depositing a silicide material on the charge storage material layer.

26. The manufacturing method according to claim 25, wherein after the step of depositing the silicide material, the method further comprises:
oxidizing the silicide material.

27. The manufacturing method according to claim 25, wherein the step (c2) further comprises:
depositing a silicide material on the third dielectric layer.

28. The manufacturing method according to claim 27, wherein after the step of depositing the silicide material, the method further comprises:
nitridizing the silicide material.

29. The manufacturing method according to claim 24, wherein the step (c3) further comprises:
depositing a silicide material on the second dielectric material layer.

30. The manufacturing method according to claim 29, wherein after the step of depositing the silicide material, the method further comprises:
oxidizing the silicide material.

31. The manufacturing method according to claim 23, wherein the step (a) further comprises:
depositing a silicide material on the substrate.

32. The manufacturing method according to claim 31, wherein after the step of depositing the silicide material, the method further comprises:
oxidizing the silicide material.

33. The manufacturing method according to claim 23, wherein the step (b) further comprises:
depositing a silicide material on the insulating material layer.

34. The manufacturing method according to claim 33, wherein after the step of depositing the silicide material, the method further comprises:
nitridizing the silicide material.

35. The manufacturing method according to claim 23, wherein between the step (d) and the step (e), the method further comprises:
implanting ions to the gate material layer.

36. The manufacturing method according to claim 23, wherein after the step (f), the method further comprises:
implanting ions to the substrate to form a source region, a drain region and a channel region, wherein the source region and the drain region are interspaced by the channel region.

37. The manufacturing method according to claim 23, further comprising a thermal nitridation process in NO, N₂O, NH₃, or ND₃ can be performed either before or after the insulating layer formation.

38. The manufacturing method according to claim 23, further comprising a plasma nitridation process can be performed either before or after the insulating layer formation.
